(19) United States
(12) Patent Application Publication
(10) Pub. No.: US 2007/0139033 A1
(43) Pub. Date: Jun. 21, 2007

(54) Active energy meter replaces wallplate used to seal single or multiple gang toggle device switch or duplex device receptacle

(76) Inventor: Alex Pogostin, Richardson, TX (US)

Correspondence Address: Alex Pogostin, 321 Ridgeview Dr., Richardson, TX, 75080, US

(21) Appl. No.: 11/642,306

(22) Filed: Dec. 20, 2006

Related U.S. Application Data
(60) Provisional application No. 60/751,759, filed on Dec. 20, 2005.

(51) Int. Cl. G01R 11/32

(52) U.S. Cl. 324/142

(57) ABSTRACT

The use of centralized electric meters to record energy consumption prevents the energy consumer from interacting with the process of energy savings. The inability of a centralized electric meter to quickly feedback energy usage, prohibits their use in interactive energy saving. The monitoring of energy consumption using a sub-metering or distributed architecture, whereby all wall mounted AC toggle switches and AC receptacles contain electric meters capable of recording and displaying energy consumption in the form of an accumulated cost of energy per outlet or electronic device, gives energy consumers the motive necessary to save energy.

### BRIEF DESCRIPTION OF THE DRAWINGS

FIG. 1 1-gang duplex device receptacle with invention mounted to backside of wallplate;

FIG. 2 1-gang toggle device switch with invention mounted to backside of wallplate;

FIG. 3 block diagram of invention.

### DETAILED DESCRIPTION

FIG. 1 the invention is mounted to the backside of a 1-gang duplex receptacle 7. Button 1 3, Button 2 4 and Button 3 1 are used to control various features of the invention. Button 1 3 and Button 2 4 are used to set the rate or cost per kilowatt hour being charged by the electric providers. The rate or cost per kilowatt hour is converted into a currency and displayed on the four digit numeric display 2. Button 1 3 increases the rate charged per kilowatt hour and Button 2 4 decreases the rate charged per kilowatt hour. Button 3 1 is used to start and stop active energy accumulation. Button 3 1 can also reset the active energy accumulated back to zero. The figure also shows a set of duplex AC receptacles 5.

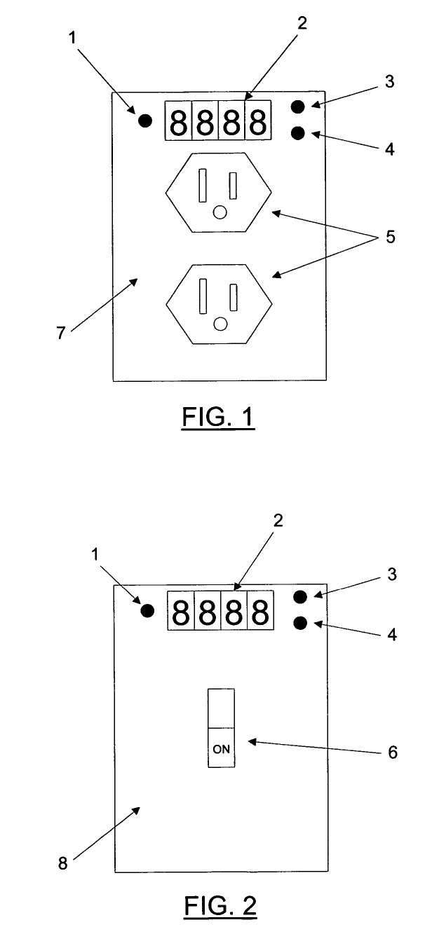

FIG. 2 the invention is mounted to the backside of a 1-gang toggle switch 8. Button 1 3, Button 2 4 and Button 3 1 are used to control various features of the invention. Button 1 3 and Button 2 4 are used to set the rate or cost per kilowatt hour being charged by the electric providers. The rate or cost per kilowatt hour is converted into a currency and displayed on the four digit numeric display 2. Button 1 3 increases the rate charged per kilowatt hour and Button 2 4 decreases the rate charged per kilowatt hour. Button 3 1 is used to start and stop active energy accumulation. Button 3 1 can also reset the active energy accumulated back to zero. The figure also shows the AC toggle switch 6.

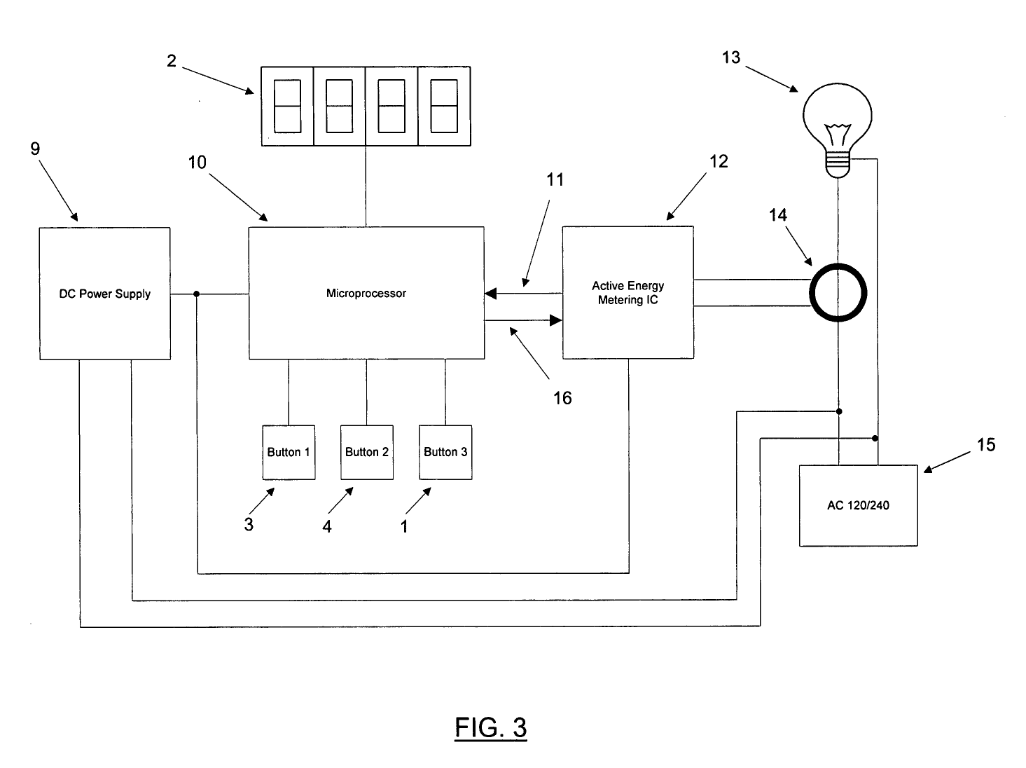

FIG. 3 shows a block diagram of the invention. The microprocessor 10 is used to control the four digit numeric display 2, interface to the active energy metering IC 12, and respond to presses applied to Button 1 3, Button 2 4 and Button 3 1. The microprocessor 10 stores in its non-volatile memory, the value of the rate or cost per kilowatt hour charged and the active energy accumulated totals. The active energy metering IC 12 interfaces with a current transformer 14 and using this current transformer, measures active energy. The incandescent lamp 13 is used in FIG. 3 as an example of an AC load, or active energy source. One side of the AC line, provided by the AC source 15, is placed through the current transformer 14. The active energy metering IC converts the active energy into binary numbers stored in registers. These registers are read through the use of a serial output signal 11 from the active energy metering IC to the microprocessor 10. Additionally, the use of a serial input 16 signal to the active energy metering IC from the microprocessor 10, allows the microprocessor 10 to initialize the active energy metering IC during power up.

What is claimed is:

1. An active energy meter mounted to the backside of a wallplate comprising: an active energy meter capable of accumulating active energy in kilowatt-hour units, mounted to the backside of a 1-gang or multiple-gang, AC toggle switch or AC receptacle wallplate.

2. An active energy meter mounted to the backside of a wallplate of claim 1, wherein a four digit numeric display is mounted in such a way as to be viewed from the front of the wallplate and through a cutout in the wallplate.

3. An active energy meter mounted to the backside of a wallplate of claim 2, wherein the four digit numeric display represents the accumulated active energy consumption converted to a currency representing energy usage. The value representing the accumulated active energy is stored in non-volatile memory.

4. An active energy meter mounted to the backside of a wallplate of claim 3, wherein three buttons are mounted to the front of the wallplate which control various functions of the active energy meter. Buttons are numbered Button 1, Button 2 and Button 3.

5. An active energy meter mounted to the backside of a wallplate of claim 4, wherein Button 1, Button 2 and Button 3 are accessible to the user of the invention and can be pressed and released using a finger.

6. An active energy meter mounted to the backside of a wallplate of claim 5, wherein Button 1 and Button 2 set the rate or cost per kilowatt hour charged by electric providers. Button 1 increases the cost per kilowatt hour and Button 2 decreases the cost per kilo-watt hour. This value is stored in non-volatile memory. The rate or cost per kilowatt hour value is then used to convert the accumulated active energy from kilowatt hour units into a number representing the cost, in currency, of the active energy consumption.

7. An active energy meter mounted to the backside of a wallplate of claim 6, wherein Button 3 is used to start or stop the accumulation of active energy, or reset the accumulated active energy to zero.

8. An active energy meter mounted to the backside of a wallplate of claim 7, wherein toggling the AC switch to off or removing power from devices plugged into the AC receptacle will stop the accumulation of the active energy accumulation and shut off the four digit numeric display.

9. An active energy meter mounted to the backside of a wallplate of claim 7, wherein the toggling of the AC switch to on or applying power to devices plugged into the AC receptacle, will turn on the four digit numeric display, recall the active energy totals previously stored in non-volatile memory and initiate a re-start of active energy accumulation.
